(19) United States
(12) Patent Application Publication
(10) Pub. No.: US 2025/0102581 A1
(43) Pub. Date: Mar. 27, 2025

(54) Systems and Methods for Non-Linear Characterization of Lithium-Ion Batteries with Bipolar Pulsing

(71) Applicant: The Trustees of Columbia University in the City of New York, New York, NY (US)

(72) Inventors: Alan G. LI, New York, NY (US); Matthias PREINDL, New York, NY (US)

(73) Assignee: The Trustees of Columbia University in the City of New York, New York, NY (US)

(21) Appl. No.: 18/891,423

(22) Filed: Sep. 20, 2024

Related U.S. Application Data
(60) Provisional application No. 63/539,781, filed on Sep. 21, 2023.

(51) Int. Cl. G01R 31/367; G01R 31/378; G01R 31/3835; G01R 31/392; H01M 10/0525; H01M 10/42

(52) U.S. Cl. CPC G01R 31/367; G01R 31/378; G01R 31/3835; G01R 31/392; H01M 10/0525; H01M 10/425; H01M 2010/4271

(57) ABSTRACT

Disclosed are systems, methods, and other implementations, including a method for battery performance analysis and management that includes measuring voltage response data for a lithium-ion battery in response to a bipolar current pulse signal applied to the lithium-ion battery, and determining, based on the measured voltage response data, using a bipolar pulse (BIP) model resultant battery characterization data representative of linear and nonlinear behavior of the lithium-ion battery. The resultant battery characterization data can include a set of multiple parameters of an equivalent circuit representation of the BIP model.

### CROSS-REFERENCE TO RELATED APPLICATIONS

This application claims priority to, and the benefit of, U.S. Provisional Application No. 63/539,781, entitled “Systems and Methods for Non-Linear Characterisation of Lithium-Ion Batteries with Bipolar Pulsing” and filed Sep. 21, 2023, the content of which is incorporated herein by reference in its entirety.

### BACKGROUND

Electrochemical systems can be characterized with pulse perturbations and the same principles remain in use today for lithium-ion batteries (LIB). By allowing a certain amount of charge to be transferred between the electrodes in a short amount of time, the system's transient dynamics can be observed. In each case using pulse perturbation, the diagnostics signal may be defined as a charge or discharge followed by a relaxation period. Pulsing allows easy calculation of the ohmic resistance which can help reduce degradation in pulsed-power applications while maintaining the power output.

Basic pulse diagnostics generally only consider the cell impedance, often fitted with an n^{th} order resistor-capacitor (NRC) equivalent circuit model (ECM). This can then provide an estimate of the state of power of the cell (pulses are known to encode information about the state and characteristics of a battery).

OCV is the dominant contributor to the battery terminal voltage and its characteristics define battery degradation modes. The non-linear effects of OCV have previously been modelled using physics-based methods. These models require extensive initial characterization and may have considerable computational complexity. Hence the recent attention to non-linear EIS (NLEIS), where a high-amplitude excitation is applied to the battery cell, creating a non-negligible OCV change that can be analyzed. Like linear EIS, NLEIS relies on sinusoidal perturbations but the amplitudes are made sufficiently large such that the output response is composed of higher-order harmonics.

### SUMMARY

Disclosed is as proposed framework to model for a bipolar pulse (BIP) for lithium-ion batteries to represent the complex voltage response governed by linear overpotentials and nonlinear open-circuit voltage (OCV) and hysteresis behavior resulting from applying a bipolar pulse with a charge and discharge currents to a lithium-ion battery cell. Both charge and discharge pulses are needed for complete characterization of the cell; the intercalation and de-intercalation processes are largely mirrored, but discrepancies arise from non-linear effects. The model disaggregates/decomposes the cell response into its linear and non-linear constituent parts using, in some examples, ten (10) parameters (more or fewer may be used). The BIP model captures the variation in charge and discharge impedance, as well as hysteresis, using multiplication and integral operations. Open-circuit voltage (OCV) and hysteresis effects are important for understanding the ‘full picture’ of the battery cell.

The BIP model characterizes thousands of pulses collected from, in the experiments conducted, 11 nickel-based cells, and the nonlinear contribution is quantified with respect to state of charge and state of health. Modelling error was bounded by 1% and is shown to be a valuable signal in its own right. Components of the BIP model were examined with ridge regression to show that nonlinearity may help with state prediction at low levels of charge, and may be strongly linked to the battery degradation level. Sensitivity analyses show the benefit of pulsing for state estimation beginning from a 0.05% net change in state of charge.

Thus, in some variations, a method for battery performance analysis and management is disclosed that includes measuring voltage response data for a lithium-ion battery in response to a bipolar current pulse signal applied to the lithium-ion battery, and determining, based on the measured voltage response data, using a bipolar pulse (BIP) model resultant battery characterization data representative of linear and nonlinear behavior of the lithium-ion battery.

Embodiments of the method may include at least some of the features described in the present disclosure, including one or more of the following features.

The bipolar current pulse signal can include at least one current pulse portion with a positive polarity, and at least one current pulse portion with a negative polarity. In some embodiments, the at least one current pulse portion with the positive polarity may include a positive rectangular pulse applied to the lithium ion battery during a first time period, and the at least one current pulse portion with the negative polarity can include a negative rectangular pulse applied to the lithium ion battery during a second time period that does not overlap with the first time period. The at least one current pulse portion with the positive polarity and the at least one current pulse portion with the negative polarity can be of durations determined to produce resultant open circuit voltage changes that are approximately linear.

The resultant battery characterization data can include a set of multiple parameters of an equivalent circuit representation of the BIP model.

The equivalent circuit representation of the BIP model can include a charge section to represent linear behavior of the battery during a charging portion of the bipolar current pulse signal, the charge section comprising impedance parameters R₀^{chg}, R₁^{chg}, C₁^{chg}, A_{D}^{chg}, corresponding to impedance components of the charge section, with A_{D}^{chg} representing a diffusion constant during the charging portion of the bipolar current pulse signal. The equivalent circuit representation can further include a discharge section to represent linear behavior of the battery during a discharging portion of the bipolar current pulse signal, the discharge section comprising impedance parameters R₀^{dis}, R₁^{dis}, C₁^{dis}, A_{D}^{dis}, corresponding to impedance components of the discharge section, with A_{D}^{dis} representing a diffusion constant during the discharging portion of the bipolar current pulse signal, and an open circuit voltage (OCV) component representing non-linear behavior of the BIP model, with the OCV component including OCV parameters S₁ and S₂.

The charge section of the equivalent circuit representation can further include a first diode component arranged in series, in a first polarity orientation, to impedance components of the charge section, and the discharge section of the equivalent circuit representation can further include a second diode component arranged in series, in a second polarity orientation different from the first polarity orientation, to impedance components of the discharge section. The first and second diode components can model the charge/discharge parameter variations for the BIP model during application of the bipolar current pulse signal.

The method may further include deriving the impedance parameters of the charge and discharge sections, and the OCV parameters through an optimization process using multiple measurement sets that includes input data sets representing bipolar pulse signals applied to battery cells, and respective voltage responses resulting from application of the bipolar pulse signals.

Deriving the impedance parameters of the charge and discharge sections, and the OCV parameters through the optimization process may include determining the impedance parameters of the charge and discharge sections, and the OCV parameters using a cost function defined as:
minimize f(θ)
subject to θ>0,
   where

$$f ( θ ) = {‖ r ‖}_{2}^{2} + a {‖ {r}^{′} ‖}_{2}^{2} ,$$

$$r ( k ) = {V}_{k} - {\hat{V}}_{k} ( θ ) ,$$

$${r}^{′} ( k ) = r ( k + 1 ) - r ( k ) , and$$

$${θ}^{T} = ( {R}_{0}^{chg} {R}_{1}^{chg} {C}_{1}^{chg} {A}_{D}^{chg} {R}_{0}^{dis} {R}_{1}^{dis} {C}_{1}^{dis} {A}_{D}^{dis} {S}_{1} {S}_{2} ) ,$$

where k is a vector index, θ is a parameter vector, r is a residual vector, and a is a weighting coefficient to control curvature of parameter fitting achieved by the optimization process

The method can further include deriving additional battery behavior data based on the set of multiple parameters of the equivalent circuit representation of the linear and nonlinear behavior of the lithium-ion battery.

Deriving the additional battery behavior can include computing OCV behavior according to:

$${V}_{OC} ( t ) = {V}_{OC} ( 0 ) + Δ {V}_{OC} ( t )$$

$$Δ {V}_{OC} ( t ) = {\int }_{0}^{t} {S}_{1} {i}_{chg} ( t ) d t + {\int }_{0}^{t} {S}_{2} {i}_{dis} ( t ) d t ,$$

where V_{OC}(0) is a steady-state OCV characteristic, ΔV_{OC}(t) is a transient OCV characteristic, and S₁, S₂<0 [F⁻¹].

The method may further include deriving at least one pulse component from one or more of, for example, the voltage response and/or the resultant battery characterization data, and predicting, using a battery state diagnostic machine learning model applied to the derived at least one pulse component, one or more of, for example, a state of health (SoH) of the lithium-ion battery and/or a state of charge (SoC) for the battery.

Predicting the one or more of the SoH or the SoC for the battery can include predicting, using a ridge-regression (RR) pulse-injection-aided machine learning (PIAML) model the one or more of, for example, the SoH and/or the SoC for the battery.

Deriving at least one pulse component can include deriving from the one or more of the voltage response or the resultant battery characterization data, one or more of a raw pulse V(t), an OCV bias V_{OC}(0), pulse harmonics V(t)−V_{OC}(0), BIP transients \hat{V}(t)−V_{OC}(0), or nonlinear components ΔV_{OC}(t)+ε(t).

In some variations, a battery performance analysis and management system is provided that includes one or more sensors to measure voltage response data for a lithium-ion battery in response to a bipolar current pulse signal applied to the lithium-ion battery, and a processor-based controller, coupled to the one or more sensors, configured to determine, based on the measured voltage response data, using a bipolar pulse (BIP) model resultant battery characterization data representative of linear and nonlinear behavior of the lithium-ion battery.

In some variations, non-transitory computer readable media is provided that includes computer instructions executable on a processor-based device to cause measurement of voltage response data for a lithium-ion battery in response to a bipolar current pulse signal applied to the lithium-ion battery, and determine, based on the measured voltage response data, using a bipolar pulse (BIP) model resultant battery characterization data representative of linear and nonlinear behavior of the lithium-ion battery.

Embodiments of the system and the computer readable media may include one or more of the features described in the present disclosure, including one or more of the features described above in relation to the method.

Other features and advantages of the invention are apparent from the following description, and from the claims.

### BRIEF DESCRIPTION OF THE DRAWINGS

These and other aspects will now be described in detail with reference to the following drawings.

FIG. 1 is a circuit diagram of an equivalent circuit for a bipolar pulse model (BIP).

FIGS. 2A-2B are graphs showing open circuit voltage (OCV) characteristics, illustrating linear approximations for small changes in SoC.

FIG. 3A is a photograph of an experimental setup and diagram of a cycling procedure used in experiments to evaluate and verify the proposed framework.

FIG. 3B includes graphs showing details of electrical behavior of a pulse train that was applied to a cell to obtain an OCV response.

FIG. 4 includes Tables providing specifications of lithium-ion cells, and details of experimental conditions used in the experiments to evaluate and verify the proposed framework.

FIG. 5 includes graphs with results obtained during the experiments to evaluate and verify the proposed framework.

FIG. 6A includes plots for BIP-1RC fitting results, showing percent error over time.

FIG. 6B includes plots showing nonlinear contributions as a function of SoC, SoH, and mean absolute percent error (MAPE).

FIG. 7 includes plots showing how contributions of overpotentials and OCV vary with net SoC change during the pulse.

FIG. 8 include plots of results of sensitivity analyses of RR-PIAML for Panasonic cell states, demonstrating how prediction error varies with input components for SoC and SoH.

FIG. 9 includes graphs for sensitivity analysis of RR-PIAML for Kokam cells, showing how SoC prediction error varies with pulse net SoC change.

FIG. 10 is a flowchart of an example procedure for battery performance analysis and management.

Like reference symbols in the various drawings indicate like elements.

### DESCRIPTION

Described herein is a proposed framework that uses bipolar pulsing as a method for nonlinear LIB characterization. To that end, a bipolar pulse (BIP) model is derived that decomposes the pulse response into its constituent overpotentials and open circuit voltage (OCV) signals. Using multiple (e.g., 10) parameters, the model explicitly accounts for charge/discharge discrepancies and hysteresis effects with no need for prior knowledge of the cell. The model's multiple parameters are used to fit voltage responses from bipolar pulsing data acquired from two types of LIB cells at various levels of temperature, charge, and health. Testing and evaluation of the frameworks was shown to have strong correlations with state of charge (SoC) values, state-of-health (SoH) values, and the BIP fitting error. The pulse components can be used to predict SoC and/or SoH using, for example, a ridge-regression (RR) pulse-injection-aided machine learning (PIAML) model. RR-PIAML analysis of the BIP components showed that the transients improve SoC estimation beyond the OCV bias, and that the nonlinearities improve SoH estimation beyond the linear components. The proposed BIP model offers a detailed understanding of the transient dynamics of bipolar pulsing, building on the convolution-defined-diffusion model, details of which are described in US 2024/0125865, entitled “Systems and Methods for Pulse-Injection Diagnostics and Prognostics for Lithium-Ion Batteries,” the content of which is incorporated herein by reference in its entirety.

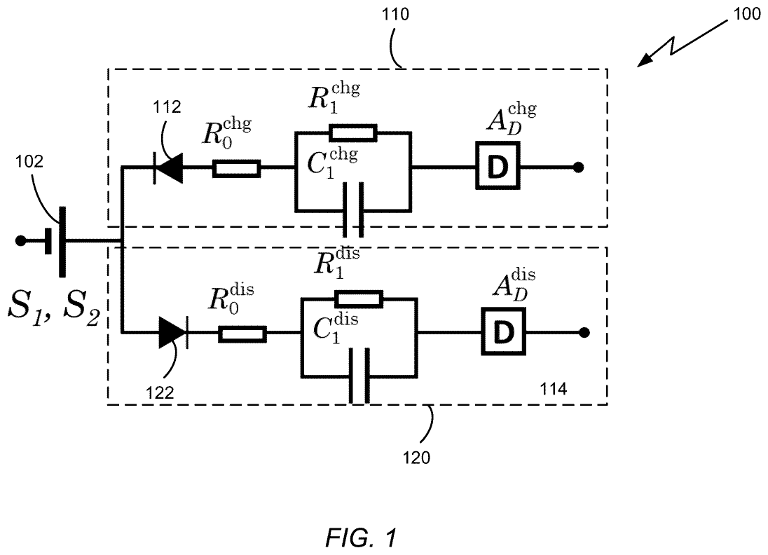

With reference to FIG. 1, a circuit diagram 100 of a BIP equivalent circuit is shown. An inversely-symmetrical rectangular bipolar current input pulse may be represented as the sum of a charge and discharge pulse i_{chg} and i_{dis}, where:

$$i ( t ) = {i}_{chg} ( t ) + {i}_{dis} ( t ) \qquad ( 1 )$$

$${i}_{chg} ( t ) = - {I}_{A} \prod ( 4 t / {T}_{p} - {t}_{0} )$$

$${i}_{dis} ( t ) = {I}_{A} \prod ( 4 t / {T}_{p} - {T}_{p} / 2 - {t}_{0} )$$

where i is the input pulse current, t is the elapsed time [s], I_{A}∈R⁺ is the pulse amplitude, Tₚ is the pulse width resulting in a portion width of Tₚ/4, t₀ is the start time, and where by definition the rectangle function Π is centered at 0 with unit width and height. Other ways to characterize the bipolar rectangular pulse signal may be used.

The equivalent circuit 100 depicted in FIG. 1 includes two sections that are active at separate portions of the pulse period. Specifically, the circuit 100 includes a charge section 110 that represents the behavior of the circuit 100 during the charging portion of the pulse signal, and a discharge section 120 that represents the circuit's behavior during the discharge portion of the bipolar pulse. The equivalent circuit 100 includes ideal diodes 112 and 122, with the first diode arranged in series to the charge section's components with a polarity that is opposite the polarity of the other diode that is arranged in series to the discharge section. The two diodes are used to model the charge/discharge parameter variations, to thus create two independent branches that interact with the OCV parameters.

Each section of the equivalent circuit 100 can be used to characterize and disaggregate the linear and non-linear behavior of a lithium-ion battery. The linear constituents of a battery response include the ohmic, charge transfer, and diffusion overpotentials components. The non-linear components include the non-linear change in open-circuit voltage. The equivalent circuit's parameters include, for the charging section 110, the impedance parameters include R₀^{chg}, R₁^{chg}, C₁^{chg}, A_{D}^{chg}, and for the discharging section the corresponding discharging impedance parameters include R₀^{dis}, R₁^{dis}, C₁^{dis}, A_{D}^{dis}. The other two parameters illustrated in FIG. 1 are S₁ and S₂ which are the OCV parameters, and based on which information about non-linear behavioral characteristics of the battery, such as open-circuit voltage (OCV) and hysteresis dynamics (the transient components) are determined. As will be discussed in greater detail below, the non-linear components of the BIP models are shown to provide reliable indicators of a cell's state(s) (represented as a State-of-Charge (SOC), State-of-Health (SoH), etc.).

Mathematically, the BIP model is given by:

$$\hat{V} ( t ) = {V}_{OC} ( {S}_{1} , {S}_{2} ) - {V}_{chg} ( {θ}_{chg} , {i}_{chg} ) - {V}_{dis} ( {θ}_{dis} , {i}_{dis} ) , \qquad ( 2 )$$

where, as noted, S₁ and S₂ are the OCV parameters illustrated in FIG. 1 as a voltage source (marked as element 102). The charge and discharge over-voltages V_{chg} and V_{dis} are functions of the current and the parameter vectors, namely:

$${θ}_{chg} = ( \begin{matrix}{R}_{0}^{chg} \\ {R}_{1}^{chg} \\ {τ}_{1}^{chg} \\ {A}_{D}^{chg}\end{matrix} ) , {θ}_{dis} = ( \begin{matrix}{R}_{0}^{dis} \\ {R}_{1}^{dis} \\ {τ}_{1}^{dis} \\ {A}_{D}^{dis}\end{matrix} ) . \qquad ( 3 )$$

The ohmic overpotential is simply a scaling of the current according to:

$${V}_{s} ( t ) = {R}_{0}^{chg} {i}_{chg} ( t ) + {R}_{0}^{dis} {i}_{dis} ( t ) . \qquad ( 4 )$$

The charge transfer overpotential, V_{ct}(t), for a single RC pair is given by a convolution (denoted by *) with the time-constant impulse response. Thus:

$${V}_{ct} ( t ) = ( \frac{{R}_{1}^{chg}}{{τ}_{1}^{chg}} ) {e}^{- t / {τ}_{1}^{chg}} * {i}_{chg} ( t ) + ( \frac{{R}_{1}^{dis}}{{τ}_{1}^{dis}} ) {e}^{- t / {τ}_{1}^{dis}} * {i}_{dis} ( t ) \qquad ( 5 )$$

The diffusion overpotential is given by convolution with the unit impulse response go (t) as:

$${V}_{D} ( t ) = {A}_{D} \cdot {∇}_{z} {V}_{OC} \cdot i ( t ) * {g}_{D} ( t ) , \qquad ( 6 )$$

$${g}_{D} ( t ) = \sqrt{t} - \sqrt{t - Δ t} ,$$

where A_{D} is the diffusion constant and ∇zV_{OC} is the OCV state-of-charge (SoC) gradient.

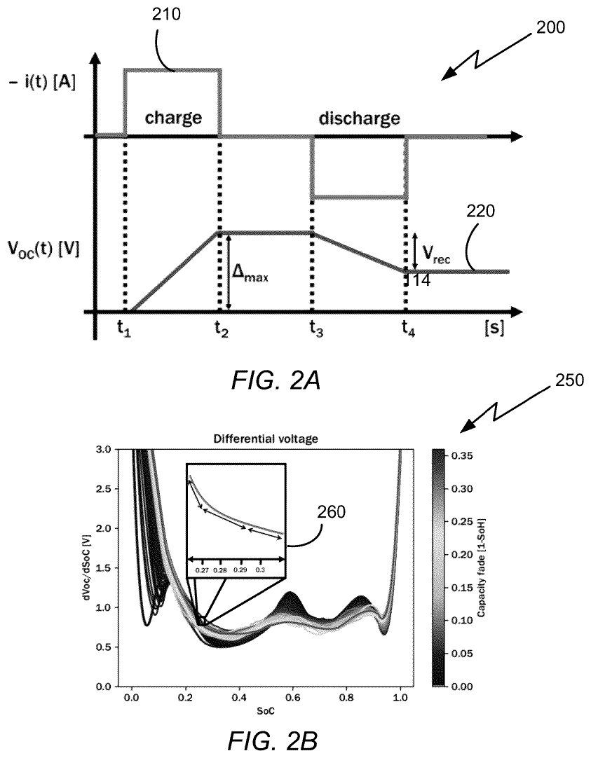

FIG. 2A is an example graph diagram 200 the open circuit characteristic during application of a bipolar pulse, with a curve 210 illustrating behavior of an applied pulsed current, −i(t), during a time interval. By assuming a sufficiently short pulse, such as the pulse 210, the OCV (the behavior of the OCV is illustrated by curve 220) changes approximately linearly during charge and discharge, meaning ∇zV_{OC} acts as a scaling factor to the fitting parameter A_{D}. Thus the BIP diffusion overpotential is given by:

$${V}_{D} ( t ) = {A}_{D}^{chg} \cdot {i}_{chg} ( t ) * {g}_{D} ( t ) + {A}_{D}^{dis} \cdot {i}_{dis} ( t ) * {g}_{D} ( t ) , \qquad ( 7 )$$

which removes any need for differential voltage characterization of the cell. FIG. 2B is a graph 250 of OCV characteristics during application of a bipolar current pulse, with inset 260 showing the linear approximations made to the different voltage curves.

Using the same assumptions, the OCV signal is governed by two parameters, the maximum change in OCV Δₘₐₓ≥0, and the recovery voltage V_{rec}∈R, linked to hysteresis. In this way a piece-wise linear function is formed. In terms of the current input, OCV is defined using,

$$\begin{matrix}{V}_{OC} ( t ) = {V}_{OC} ( 0 ) + Δ {V}_{OC} ( t ) \\ Δ {V}_{O C} ( t ) = {\int }_{0}^{t} {S}_{1} {i}_{c h g} ( t ) d t + {\int }_{0}^{t} {S}_{2} {i}_{d i s} ( t ) dt ,\end{matrix} \qquad ( 8 )$$

where the steady-state OCV V_{OC}(0) is separated from the transient ΔV_{OC}(t), and S₁, S₂<0 [F⁻¹] are related to Δₘₐₓ and V_{rec} according to:

$$\begin{matrix}{Δ}_{max} = \vert {S}_{1} {I}_{A} ( {t}_{2} - {t}_{1} ) \vert \\ {V}_{r e c} = \vert {S}_{2} {I}_{A} ( {t}_{2} - {t}_{1} ) \vert ,\end{matrix} \qquad ( 9 )$$

The amount of hysteresis, which represents a measure of nonlinearity of an electrical cell, is captured by the difference |Δₘₐₓ−V_{rec}|, which is only zero in a linear system.

The proposed BIP model has the advantage of accounting for charge and discharge variations, OCV change, and hysteresis effects. There is no need for any prior knowledge about the cell. Since most conventional equivalent circuit models either require an additional physics-based OCV estimator, use an inaccurate look-up-table, or might even forgo OCV estimation entirely, the proposed framework and model combines mathematical simplicity with physical relevance.

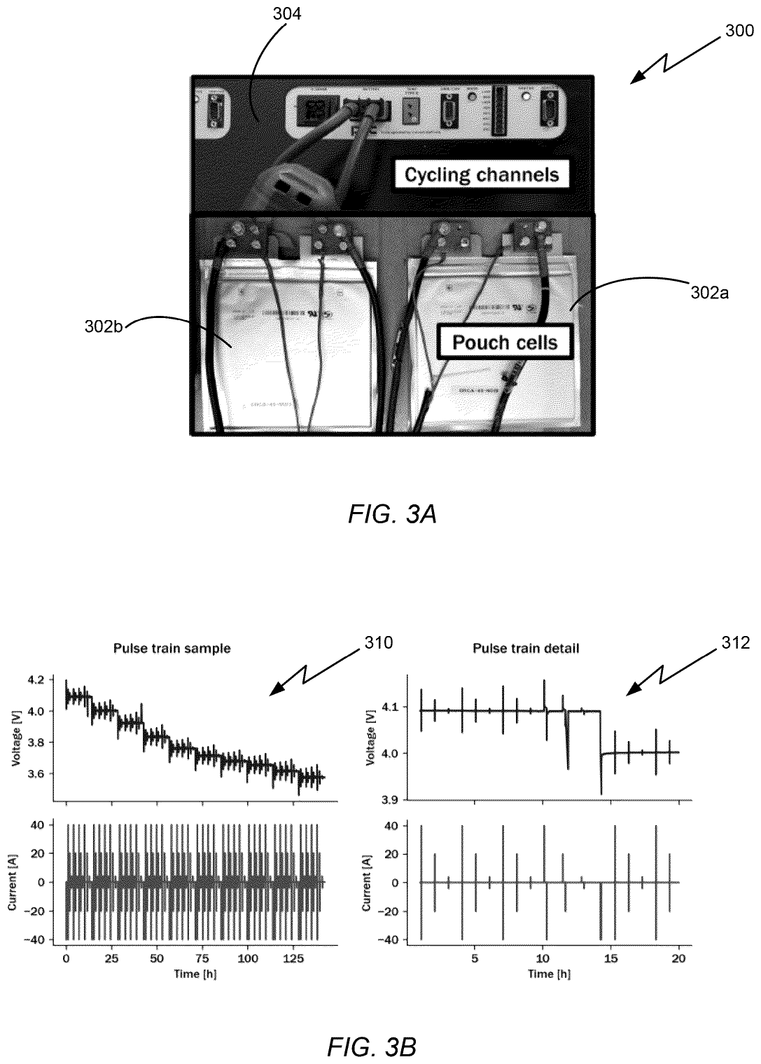

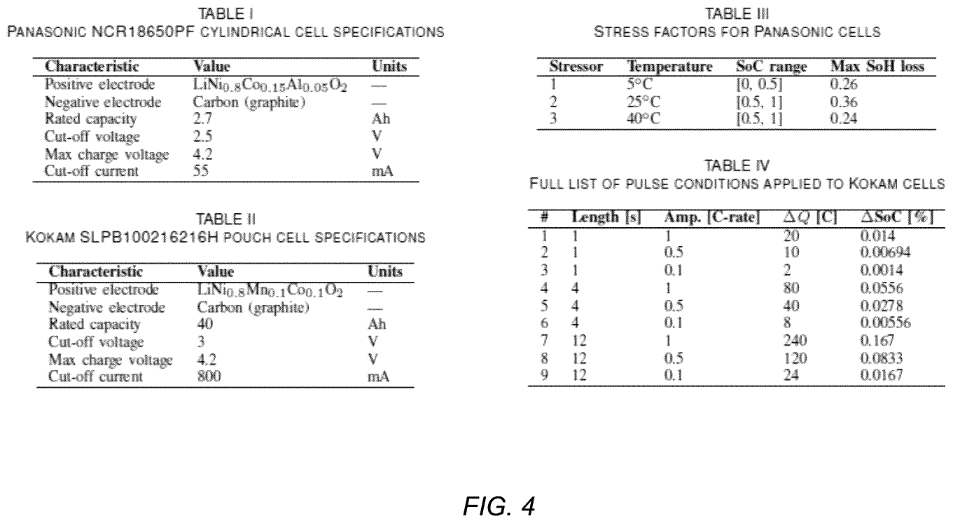

Verification and application of the BIP model were performed using data from commercial Panasonic cylindrical cells and Kokam pouch cells. More particularly, FIG. 3A includes a photograph 300 of the experimental setup and diagram of a cycling procedure for Kokam cells, showing the Kokam cells 302a-b and a cycler 304. FIG. 3B includes graphs 310 and 312 showing details of the behavior (in terms of the time-dependent voltage and current) of a pulse train that was applied to the cell to obtain the OCV response to the pulse train. FIG. 4 includes Tables I and II providing, respectively, specifications of a Panasonic NCR18650PF cylindrical cell and a Kokam SLPB100216216H pouch cell. Pulse responses lasting 2 min with 1 C-rate amplitude, and 10 Hz sampling, were obtained from 9 Panasonic cells subject to 3 different stress factors, that are summarized in Table III of FIG. 4. Cells were cycled in three regimes with a Neware BTS4000 series 5V6A cycler and 25 L temperature chambers with a maximum range of [5, 60]° C. First, a capacity check was performed with a C/20 pseudo-OCV discharge. Integrating the discharge current yielded the maximum capacity Qₘₐₓ of the cell. After recharging at C/5, the pulse train was applied. In the pulse train a series of pulses were applied at decreasing discrete SoC levels with at least 1 hour rest preceding the pulse. The SoC levels were calculated using the relationship:

$$S oC ( t ) = \frac{η \int i ( t ) dt}{{Q}_{max} ( t )} , \qquad ( 10 )$$

where it was assumed a coulombic efficiency η=0.99. Once the pulse train reached the cutoff voltage, the cell was then subject to 50 constant-current degradation cycles and the entire process was repeated until failure.

To investigate the effects of pulse length and amplitude, bipolar pulses were applied to two (2) Kokam cells with a PEC SBT0550 19 kW cycler at ambient temperature of 25° C. Pulses had amplitudes selected from the set {0.1, 0.5, 1} C-rate and lengths selected from the set {1, 4, 12} s, with a 1 kHz sampling rate. A total of nine (9) pulse shapes were used, whose characteristics are summarized in Table IV of FIG. 4. These different pulse shaped can be labelled by the change in SoC, denoted as ΔSoC, calculated using the nominal maximum capacity Q₀ as shown in Table II. The quantity ΔSoC can be computed according to the expression:

$$Δ S o C ( t ) = \frac{{\int }_{0}^{{T}_{p}} \vert i ( t ) \vert dt}{{Q}_{0}} . \qquad ( 11 )$$

Cycling was performed with a capacity check and pulse train, but the nine pulses were applied at each SoC level with at least 1 hour between pulses, and there were no degradation cycles. Note that the maximum ΔSoC for the pulses applied to the Kokam cells was 0.0167%, while the Panasonic cells were subjected to a constant ΔSoC=1.67%.

In a first step of using proposed framework, the BIP model was applied to disaggregate the bipolar voltage response to separate the linear from the nonlinear components. In some embodiments, circuit elements were fitted through the MATLAB scatter-search global optimization method with the following cost function:
minimize f(θ)
subject to θ>0.

For the above cost function, the following relationships were defined:

$$\begin{matrix}f ( θ ) = {‖ r ‖}_{2}^{2} + a {‖ {r}^{′} ‖}_{2}^{2} , \\ r ( k ) = {V}_{k} - {\hat{V}}_{k} ( θ ) , \\ {r}^{′} ( k ) = r ( k + 1 ) - r ( k ) , and \\ {θ}^{T} = ( {R}_{0}^{c h g} {R}_{1}^{c h g} {C}_{1}^{c h g} {A}_{D}^{c h g} {R}_{0}^{d i s} {R}_{1}^{d i s} {C}_{1}^{d i s} {A}_{D}^{d i s} {S}_{1} {S}_{2} ) ,\end{matrix} \qquad ( 12 )$$

where k is the vector index, θ is the parameter vector (corresponding to the equivalent circuit of FIG. 1, r is the residual vector, and the weighting of the sum of the squared residual differences is set to a=10³ to improve the curvature of the fit. Other optimization processes may be used.

Next, the determined parameters were used to reconstruct the pulse components as detailed above in Equations (2)-(9). The terminal voltage can be written in terms of the overpotentials Vₒᵥₚ, the OCV, and the BIP modelling error of:

$$V ( t ) = {V}_{OC} ( 0 ) + Δ {V}_{OC} ( t ) - {V}_{o v p} ( t ) + ε ( t ) , where ε ( t ) = V ( t ) - \hat{V} ( t ) , and percent error = \frac{ε ( t )}{V ( t )} \times 1 0. \qquad ( 13 )$$

The hypothesis is that the sum ΔV_{OC}(t)+ε(t) forms the nonlinear components of the pulse whose contribution can be quantified with the voltage-time integral:

$${𝒱}_{N L} = {\int }_{0}^{{T}_{p}} \vert Δ {V}_{O C} ( t ) + ε ( t ) \vert dt \qquad ( 14 )$$

which can then be normalized as a percentage, as follows:

$$Percent contribution = \frac{{𝒱}_{N L}}{{\int }_{0}^{{T}_{p}} \vert Δ V ( t ) \vert dt} \times 100. \qquad ( 15 )$$

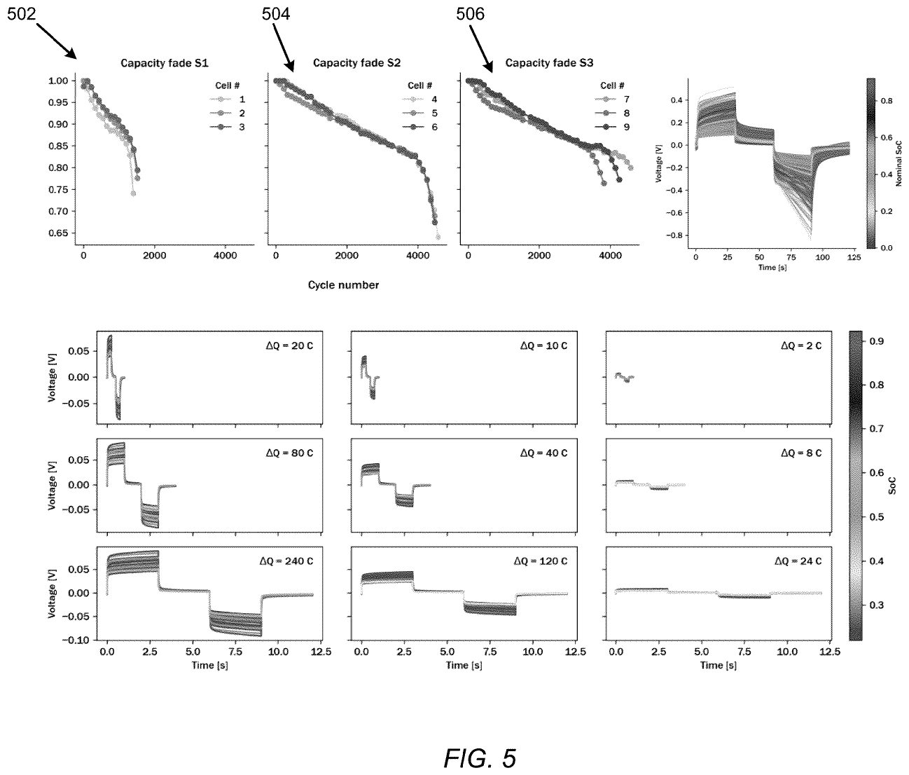

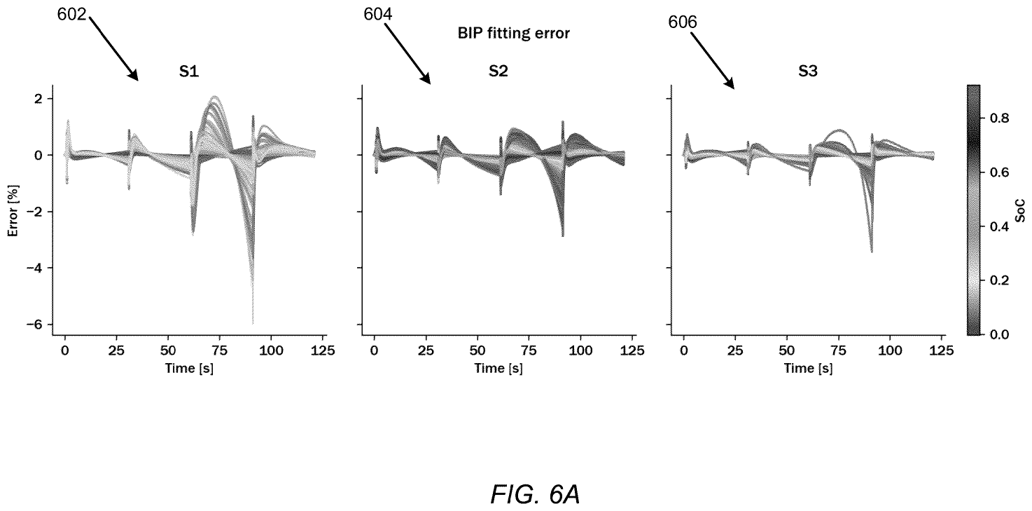

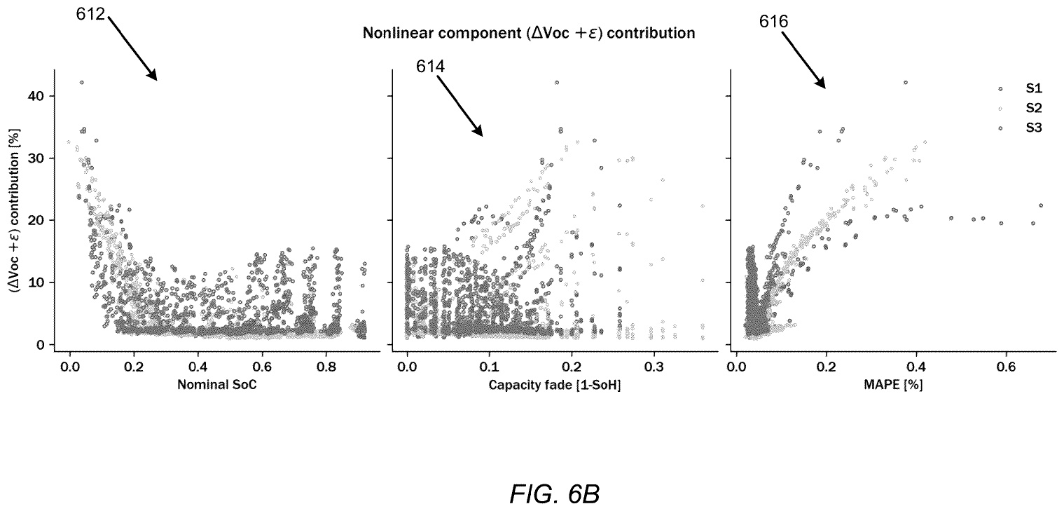

Plots 602, 604, and 606 of the ε(t) percent error function are shown in FIG. 6A for each pulse, color/shade coded by the nominal pulse SoC. The time varying percent error is mostly bounded by 1%, indicating good agreement with the data, though there are some spikes in error at transitions and at the times corresponding to the discharge portion. These instances are confined mainly to low SoC. To better understand this behavior, the total nonlinear contribution against SoC, SoH, and the mean absolute percent error (MAPE) were plotted, as provided in plots 612, 614, and 616 of FIG. 6B. Together, the plots of FIG. 6B are particularly striking. They show that ν_{NL} increases sharply at low SoC with small variation between stressors. When plotted against capacity fade, the trend is more subtle. While it is clear that ν_{NL} increases as the cell degrades, it appears to be temperature and cell-dependent. Like the capacity fade graphs 502, 504, and 506 of FIG. 5, there are three (3) clear branches in the data for each stressor that may correspond to the cell inhomogeneities. Finally, the plot against MAPE confirms that nonlinearity is correlated with the modelling error but the relationship is complex and highly temperature dependent. This is because it captures both the piece-wise linear OCV and hysteresis change, as well as the higher-order dynamics seen in ε(t).

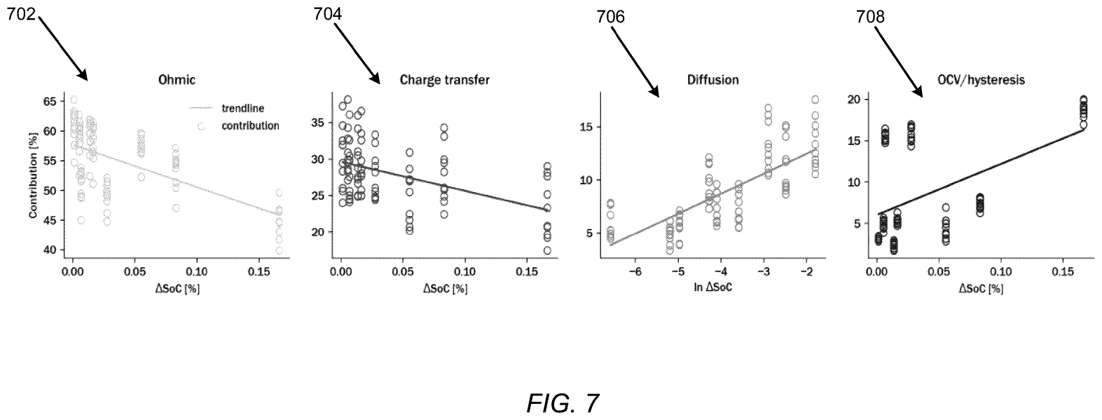

Other components may be examined individually, as illustrated in FIG. 7, showing disaggregation of the Kokam cells pulse components, including plots showing how contributions of the overpotentials and OCV vary with net SoC change during the pulse. Particularly, the ohmic and charge transfer contributions (as provided in graphs 702 and 704, respectively) dominate during short perturbations. However, as the number of coulombs increases, the diffusion contribution (plotted in graph 706) increases significantly. The OCV contribution (as illustrated in graph 708) becomes more significant as well. This conforms with the behavioral expectations of the cell because the pulses with larger ΔSoC have lower fundamental frequencies, thus triggering lower-frequency dynamics.

Beyond contribution analysis, decomposing the bipolar pulse voltage response into its constituent parts allows performing sensitivity analysis of the amount of SoC and SoH information encoded in bipolar pulsing. Specific components of interest include:
1) Raw pulse V(t),
2) OCV bias V_{OC}(0),
3) Pulse harmonics V(t)−V_{OC}(0),
4) BIP transients \hat{V}(t)−V_{OC}(0), and
5) Nonlinear components ΔV_{OC}(t)+ε(t).

Note that the difference between the harmonics and the transients is the modelling error & (t), and the difference between the harmonics and ΔV_{OC}(t)+ε(t) is the overpotentials Vₒᵥₚ(t). These components can be used to assess how information in the raw data is lost or altered in the BIP fit.

The pulse components predict the SoC and/or SoH using a ridge-regression (RR) pulse-injection-aided machine learning (PIAML) model. RR predictions can be defined as,

$$y = {W}_{R R}^{T} x , \qquad ( 16 )$$

where y∈R is the output, x∈Rⁿ is the input data vector, and n is the length of the feature vector w_{RR} and x. The feature vector can be calculated using a standard ridge regression procedure. For example, a scikit-learn Python library can be used with the equation:

$${w}_{R R} = {( λ I + {X}^{T} X )}^{- 1} {X}^{T} Y , \qquad ( 17 )$$

where X∈R^{m×n} as the matrix of training data, Y∈R^{m} as the vector of known outputs, and m is the size of the training data, randomly selected as 80% of the total dataset. A regularization of λ=0.005 and an 80-20 training-test random split of the dataset can be used, In the experiments and studies held, ten (10) trials were performed to obtain the results.

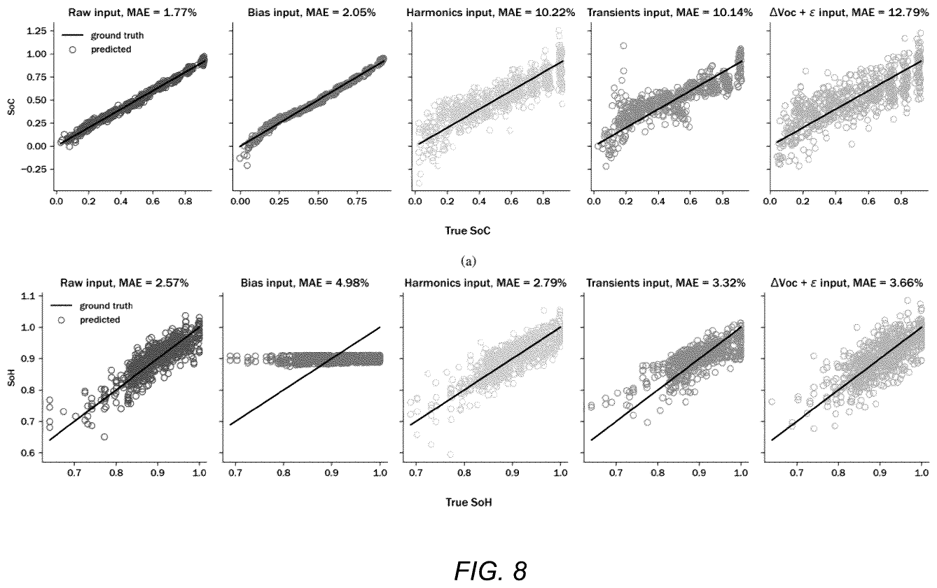

State predictions using the combined Panasonic cell dataset are provided in FIG. 8, showing results of sensitivity analyses of RR-PIAML for Panasonic cell states, demonstrating how prediction error varies with input components for SoC and SoH. The SoC is predicted with less than 2% error using the raw pulse. However, accuracy deteriorates as components are lost. The OCV bias remains a good predictor of SoC, as expected, but with issues at low SoC. The BIP transients are slightly better predictors of SoC than the pulse harmonics, suggesting that the loss of the error signal has little effect on the accuracy. Regarding SoH, the OCV bias appears to be uncorrelated, as expected. This means that the raw and harmonics inputs result in near-identical fits. Meanwhile, the transients perform worse, indicating that the BIP model retains key features of the SoH.

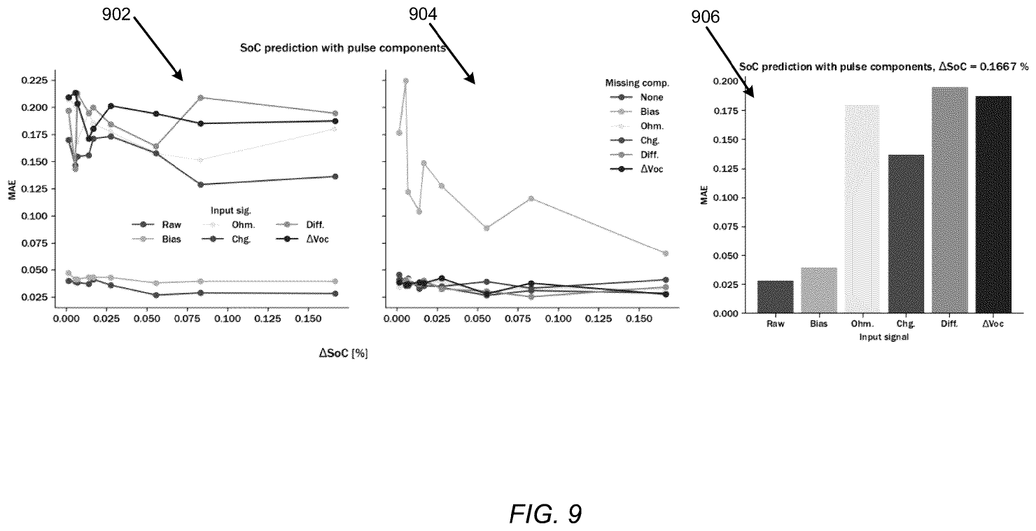

FIG. 9 includes graphs for sensitivity analysis of RR-PIAML for Kokam cells, showing how SoC prediction error varies with pulse net SoC change (graphs 902 and 904), and input components (graph 906). As shown in the graphs of FIG. 9, state prediction using the Kokam data allows for the SoC prediction error to be analyzed with respect to ΔSoC. The graphs demonstrate that as the coulombs passed goes to 0, the pulse predictive capability equals that of the OCV bias. For ΔSoC>0.05% the pulse improvement becomes clear, consistently decreasing the mean absolute SoC error by approximately 0.02 relative to the bias. When components are subtracted from the raw pulse, it is evident that the loss of the bias voltage leads to the greatest loss in accuracy. Yet as the value of coulombs passed increases, the prediction error using pulse harmonics decreases, confirming the value of pulsing. The bar graph 906 of FIG. 9 displays the results for the ΔSoC=0.1667%, indicating that important components for predicting SoC in this scenario are the bias and the charge-transfer contributions.

In summary then, described herein is a proposed framework configured to determine or predict state information for lithium-ion batteries. The proposed framework uses a proposed bipolar pulse (BIP) model under which short bipolar pulses (with one segment of the pulse having a first polarity and another segment having the opposite polarity) are used to trigger an open circuit voltage response at the battery's terminals. The BIP model characterizes the linear and nonlinear dynamics of LIB cells. In the example embodiments of the proposed BIP model, the model is composed of 10 parameters for an equivalent circuit representation of the BIP model. As discussed above, the framework, and BIP model, was used to fit voltage responses from bipolar pulsing data acquired from two types of LIB cells at various levels of temperature, charge, and health. Nonlinear pulse dynamics were shown to have strong correlations with SoC, SoH, and the BIP fitting error. Furthermore, RR-PIAML analysis of the BIP components showed that the transients improve SoC estimation beyond the OCV bias, and that the nonlinearities improve SoH estimation beyond the linear components.

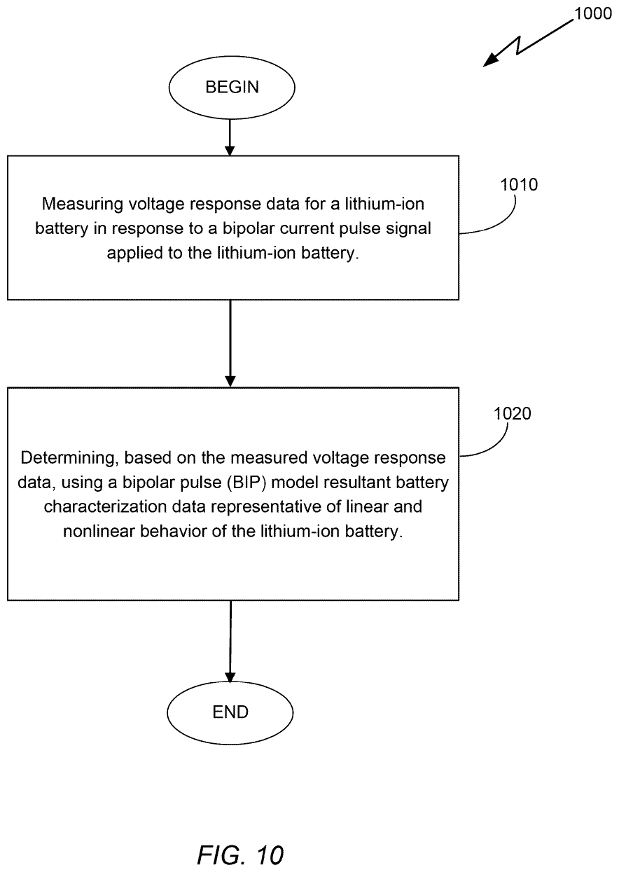

Thus, with reference to FIG. 10, a flowchart of an example procedure 1000 for battery performance analysis and management is disclosed. The procedure 1000 includes measuring 1010 voltage response data for a lithium-ion battery in response to a bipolar current pulse signal applied to the lithium-ion battery, and determining 1020, based on the measured voltage response data, using a bipolar pulse (BIP) model resultant battery characterization data representative of linear and nonlinear behavior of the lithium-ion battery.

In some embodiments, the bipolar current pulse signal can include at least one current pulse portion with a positive polarity, and at least one current pulse portion with a negative polarity. In such embodiments, the at least one current pulse portion with the positive polarity comprises a positive rectangular pulse applied to the lithium ion battery during a first time period, and the at least one current pulse portion with the negative polarity comprises a negative rectangular pulse applied to the lithium ion battery during a second time period that does not overlap with the first time period (see also FIG. 2A for an example of a rectangular bipolar current pulse signal). In various examples, the at least one current pulse portion with the positive polarity and the at least one current pulse portion with the negative polarity are of durations determined to produce resultant open circuit voltage changes that are approximately linear.

In some examples, the resultant battery characterization data can include a set of multiple parameters of an equivalent circuit representation of the BIP model. The equivalent circuit representation of the BIP model may include a charge section to represent linear behavior of the battery during a charging portion of the bipolar current pulse signal, the charge section comprising impedance parameters R₀^{chg}, R₁^{chg}, C₁^{chg}, A_{D}^{chg}, corresponding to impedance components of the charge section, with A_{D}^{chg} representing a diffusion constant during the charging portion of the bipolar current pulse signal. The equivalent circuit representation of the BIP model can also include a discharge section to represent linear behavior of the battery during a discharging portion of the bipolar current pulse signal, the discharge section comprising impedance parameters R₀^{dis}, R₁^{dis}, C₁^{dis}, A_{D}^{dis}, corresponding to impedance components of the discharge section, with A_{D}^{dis} representing a diffusion constant during the discharging portion of the bipolar current pulse signal. And the equivalent circuit representation can further include an open circuit voltage (OCV) component representing non-linear behavior of the BIP model, with the OCV component including OCV parameters S₁ and S₂.

In various embodiments, the charge section of the equivalent circuit representation can further include a first diode component arranged in series, in a first polarity orientation, to impedance components of the charge section, and the discharge section of the equivalent circuit representation can further include a second diode component arranged in series, in a second polarity orientation different from the first polarity orientation, to impedance components of the discharge section. The first and second diode components can model the charge/discharge parameter variations for the BIP model during application of the bipolar current pulse signal.

In various embodiments, the procedure can further include deriving the impedance parameters of the charge and discharge sections and the OCV parameters through an optimization process using multiple measurement sets comprising input data sets representing bipolar pulse signals applied to battery cells, and respective voltage responses resulting from application of the bipolar pulse signals. In such embodiments, deriving the impedance parameters of the charge and discharge sections, and the OCV parameters can include determining the impedance parameters of the charge and discharge sections, and the OCV parameters using a cost function defined as:
minimize f(θ)
subject to θ>0,
   with:

$$\begin{matrix}f ( θ ) = {‖ r ‖}_{2}^{2} + a {‖ {r}^{′} ‖}_{2}^{2} , \\ r ( k ) = {V}_{k} - {\hat{V}}_{k} ( θ ) , \\ {r}^{′} ( k ) = r ( k + 1 ) - r ( k ) , and \\ {θ}^{T} = ( {R}_{0}^{c h g} {R}_{1}^{c h g} {C}_{1}^{c h g} {A}_{D}^{c h g} {R}_{0}^{d i s} {R}_{1}^{d i s} {C}_{1}^{d i s} {A}_{D}^{d i s} {S}_{1} {S}_{2} ) ,\end{matrix}$$

where k is a vector index, θ is the parameter vector, r is a residual vector, and a is a weighting coefficient to control curvature of parameter fitting achieved by the optimization process.

In some embodiment, the procedure may further include deriving additional battery behavior data based on the set of multiple parameters of the equivalent circuit representation of the linear and nonlinear behavior of the lithium-ion battery. Deriving the additional battery behavior can include computing OCV behavior according to:

$$\begin{matrix}{V}_{OC} ( t ) = {V}_{OC} ( 0 ) + Δ {V}_{OC} ( t ) \\ Δ {V}_{O C} ( t ) = {\int }_{0}^{t} {S}_{1} {i}_{c h g} ( t ) d t + {\int }_{0}^{t} {S}_{2} {i}_{d i s} ( t ) d t ,\end{matrix}$$

where V_{OC}(0) is a steady-state OCV characteristic, ΔV_{OC}(t) is a transient OCV characteristic, and S₁, S₂<0 [F⁻¹].

The procedure 1000 can further include deriving at least one pulse component from one or more of: the voltage response, or the resultant battery characterization data, and predicting, using a battery state diagnostic machine learning model applied to the derived at least one pulse component, one or more of, for example, state of health (SoH) of the lithium-ion battery and/or state of charge (SoC) for the battery. Predicting the one or more of the SoH and/or the SoC for the battery can include predicting, using a ridge-regression (RR) pulse-injection-aided machine learning (PIAML) model, the one or more of the SoH or the SoC for the battery.

In various examples, the method may further include deriving at least one pulse component (e.g., one or more of raw pulse V(t), OCV bias V_{OC}(0), pulse harmonics V(t)−V_{OC}(0), BIP transients \hat{V}(t)−V_{OC}(0), or nonlinear components ΔV_{OC}(t)+ε(t)) from one or more of, for example, the voltage response and/or the resultant battery characterization data. In such examples, the method may additionally include predicting, using a ridge-regression (RR) pulse-injection-aided machine learning (PIAML) model applied to the derived at least one pulse component, one or more of, for example, the state-of-health (SoH) of the lithium-ion battery and/or the state-of-charge (Soc) for the lithium-ion battery.

Implementing the proposed framework and performing the various techniques and operations described herein may be facilitated by a controller device(s) (e.g., a processor-based computing device). Such a controller device may include a processor-based device such as a computing device, and so forth, that typically includes a central processor unit or a processing core. The device may also include one or more dedicated learning machines (e.g., neural networks, implementing machine learning architectures such as convolutional neural networks (CNN), feed-forward neural networks, recurrent neural networks (RNN), etc.) that may be part of the CPU or processing core.

In addition to the CPU, the system includes main memory, cache memory and bus interface circuits. The controller device may include a mass storage element, such as a hard drive (solid state hard drive, or other types of hard drive), or flash drive associated with the computer system. The controller device may further include a keyboard, or keypad, or some other user input interface, and a monitor, e.g., an LCD (liquid crystal display) monitor, that may be placed where a user can access them.

The controller device is configured to facilitate, for example, battery performance analysis and management. The storage device may thus include a computer program product that when executed on the controller device (which, as noted, may be a processor-based device) causes the processor-based device to perform operations to facilitate the implementation of procedures and operations described herein. The controller device may further include peripheral devices to enable input/output functionality. Such peripheral devices may include, for example, flash drive (e.g., a removable flash drive), or a network connection (e.g., implemented using a USB port and/or a wireless transceiver), for downloading related content to the connected system. Such peripheral devices may also be used for downloading software containing computer instructions to enable general operation of the respective system/device. Alternatively and/or additionally, in some embodiments, special purpose logic circuitry, e.g., an FPGA (field programmable gate array), an ASIC (application-specific integrated circuit), a DSP processor, a graphics processing unit (GPU), application processing unit (APU), etc., may be used in the implementations of the controller device. Other modules that may be included with the controller device may include a user interface to provide or receive input and output data. The controller device may include an operating system.

Computer programs (also known as programs, software, software applications or code) include machine instructions for a programmable processor, and may be implemented in a high-level procedural and/or object-oriented programming language, and/or in assembly/machine language. As used herein, the term “machine-readable medium” refers to any non-transitory computer program product, apparatus, and/or device (e.g., magnetic discs, optical disks, memory, Programmable Logic Devices (PLDs)) used to provide machine instructions and/or data to a programmable processor, including a non-transitory machine-readable medium that receives machine instructions as a machine-readable signal.

In some embodiments, any suitable computer readable media can be used for storing instructions for performing the processes/operations/procedures described herein. For example, in some embodiments computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as flash memory, electrically programmable read only memory (EPROM), electrically erasable programmable read only Memory (EEPROM), etc.), any suitable media that is not fleeting or not devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Although particular embodiments have been disclosed herein in detail, this has been done by way of example for purposes of illustration only, and is not intended to be limiting with respect to the scope of the appended claims, which follow. Features of the disclosed embodiments can be combined, rearranged, etc., within the scope of the invention to produce more embodiments. Some other aspects, advantages, and modifications are considered to be within the scope of the claims provided below. The claims presented are representative of at least some of the embodiments and features disclosed herein. Other unclaimed embodiments and features are also contemplated.

What is claimed is:

1. A method for battery performance analysis and management comprising:
measuring voltage response data for a lithium-ion battery in response to a bipolar current pulse signal applied to the lithium-ion battery; and
determining using a bipolar pulse (BIP) model, based on the measured voltage response data, resultant battery characterization data representative of linear and nonlinear behavior of the lithium-ion battery.

2. The method of claim 1, wherein the bipolar current pulse signal comprises:
at least one current pulse portion with a positive polarity, and at least one current pulse portion with a negative polarity.

3. The method of claim 2, wherein the at least one current pulse portion with the positive polarity comprises a positive rectangular pulse applied to the lithium ion battery during a first time period, and the at least one current pulse portion with the negative polarity comprises a negative rectangular pulse applied to the lithium ion battery during a second time period that does not overlap with the first time period.

4. The method of claim 3, wherein the at least one current pulse portion with the positive polarity and the at least one current pulse portion with the negative polarity are of durations determined to produce resultant open circuit voltage changes that are approximately linear.

5. The method of claim 1, wherein the resultant battery characterization data comprises a set of multiple parameters of an equivalent circuit representation of the BIP model.

6. The method of claim 5, wherein the equivalent circuit representation of the BIP model includes:
a charge section to represent linear behavior of the battery during a charging portion of the bipolar current pulse signal, the charge section comprising impedance parameters R₀^{chg}, R₁^{chg}, C₁^{chg}, A_{D}^{chg}, corresponding to impedance components of the charge section, wherein A_{D}^{chg} represents a diffusion constant during the charging portion of the bipolar current pulse signal;
a discharge section to represent linear behavior of the battery during a discharging portion of the bipolar current pulse signal, the discharge section comprising impedance parameters R₀^{dis}, R₁^{dis}, C₁^{dis}, A_{D}^{dis}, corresponding to impedance components of the discharge section, wherein A_{D}^{dis} represents a diffusion constant during the discharging portion of the bipolar current pulse signal; and
an open circuit voltage (OCV) component representing non-linear behavior of the BIP model, the OCV component comprising OCV parameters S₁ and S₂.

7. The method of claim 6, wherein the charge section of the equivalent circuit representation further includes a first diode component arranged in series, in a first polarity orientation, to impedance components of the charge section;
wherein the discharge section of the equivalent circuit representation further includes a second diode component arranged in series, in a second polarity orientation different from the first polarity orientation, to impedance components of the discharge section;
and wherein the first and second diode components model the charge/discharge parameter variations for the BIP model during application of the bipolar current pulse signal.

8. The method of claim 6, further comprising:
deriving the impedance parameters of the charge and discharge sections, and the OCV parameters through an optimization process using multiple measurement sets comprising input data sets representing bipolar pulse signals applied to battery cells, and respective voltage responses resulting from application of the bipolar pulse signals.

9. The method of claim 8, wherein deriving the impedance parameters of the charge and discharge sections, and the OCV parameters through the optimization process comprises:
determining the impedance parameters of the charge and discharge sections, and the OCV parameters using a cost function defined as:
minimize f(θ)
subject to θ>0,
wherein:
$$\begin{matrix}f ( θ ) = {‖ r ‖}_{2}^{2} + a {‖ {r}^{′} ‖}_{2}^{2} , \\ r ( k ) = {V}_{k} - {\hat{V}}_{k} ( θ ) , \\ {r}^{′} ( k ) = r ( k + 1 ) - r ( k ) , and \\ {θ}^{T} = ( {R}_{0}^{c h g} {R}_{1}^{c h g} {C}_{1}^{c h g} {A}_{D}^{c h g} {R}_{0}^{d i s} {R}_{1}^{d i s} {C}_{1}^{d i s} {A}_{D}^{d i s} {S}_{1} {S}_{2} ) ,\end{matrix}$$
where k is a vector index, θ is a parameter vector, r is a residual vector, and a is a weighting coefficient to control curvature of parameter fitting achieved by the optimization process.

10. The method of claim 5, further comprising:
deriving additional battery behavior data based on the set of multiple parameters of the equivalent circuit representation of the linear and nonlinear behavior of the lithium-ion battery.

11. The method of claim 10, wherein deriving the additional battery behavior comprises:
computing OCV behavior according to:
$$\begin{matrix}{V}_{OC} ( t ) = {V}_{OC} ( 0 ) + Δ {V}_{OC} ( t ) \\ Δ {V}_{O C} ( t ) = {\int }_{0}^{t} {S}_{1} {i}_{c h g} ( t ) d t + {\int }_{0}^{t} {S}_{2} {i}_{d i s} ( t ) d t ,\end{matrix}$$
where V_{OC}(0) is a steady-state OCV characteristic, ΔV_{OC}(t) is a transient OCV characteristic, and S₁, S₂<0 [F⁻¹].

12. The method of claim 1, further comprising:
deriving at least one pulse component from one or more of: the voltage response, or the resultant battery characterization data; and
predicting, using a battery state diagnostic machine learning model applied to the derived at least one pulse component, one or more of: a state of health (SoH) of the lithium-ion battery, or a state of charge (SoC) for the battery.

13. The method of claim 12, wherein predicting the one or more of the SoH or the SoC for the battery comprises:
predicting, using a ridge-regression (RR) pulse-injection-aided machine learning (PIAML) model the one or more of the SoH or the SoC for the battery.

14. The method or claim 12, wherein deriving at least one pulse component comprises:
deriving from the one or more of the voltage response or the resultant battery characterization data, one or more of a raw pulse V(t), an OCV bias V_{OC}(0), pulse harmonics V(t)−V_{OC}(0), BIP transients V(t)−V_{OC}(0), or nonlinear components ΔV_{OC}(t)+ε(t).

15. A battery performance analysis and management system comprising:
one or more sensors to measure voltage response data for a lithium-ion battery in response to a bipolar current pulse signal applied to the lithium-ion battery; and
a processor-based controller, coupled to the one or more sensors, configured to determine using a bipolar pulse (BIP) model, based on the measured voltage response data, resultant battery characterization data representative of linear and nonlinear behavior of the lithium-ion battery.

16. The system of claim 15, wherein the bipolar current pulse signal comprises at least one current pulse portion with a positive polarity, and at least one current pulse portion with a negative polarity, wherein the at least one current pulse portion with the positive polarity comprises a positive rectangular pulse applied to the lithium ion battery during a first time period, and the at least one current pulse portion with the negative polarity comprises a negative rectangular pulse applied to the lithium ion battery during a second time period that does not overlap with the first time period.

17. The system of claim 15, wherein the resultant battery characterization data comprises a set of multiple parameters of an equivalent circuit representation of the BIP model, wherein the equivalent circuit representation of the BIP model includes:
a charge section to represent linear behavior of the battery during a charging portion of the bipolar current pulse signal, the charge section comprising impedance parameters R₀^{chg}, R₁^{chg}, C₁^{chg}, A_{D}^{chg}, corresponding to impedance components of the charge section, wherein A_{D}^{chg} represents a diffusion constant during the charging portion of the bipolar current pulse signal;
a discharge section to represent linear behavior of the battery during a discharging portion of the bipolar current pulse signal, the discharge section comprising impedance parameters R₀^{dis}, R₁^{dis}, C₁^{dis}, A_{D}^{dis}, corresponding to impedance components of the discharge section, wherein A_{D}^{dis} represents a diffusion constant during the discharging portion of the bipolar current pulse signal; and
an open circuit voltage (OCV) component representing non-linear behavior of the BIP model, the OCV component comprising OCV parameters S₁ and S₂.

18. The system of claim 15, wherein the processor-based controller is further configured to:
derive the impedance parameters of the charge and discharge sections, and the OCV parameters through an optimization process using multiple measurement sets comprising input data sets representing bipolar pulse signals applied to battery cells, and respective voltage responses resulting from application of the bipolar pulse signals, including to:
determine the impedance parameters of the charge and discharge sections, and the OCV parameters using a cost function defined as:
minimize f(θ)
subject to θ>0,
wherein:
$$\begin{matrix}f ( θ ) = {‖ r ‖}_{2}^{2} + a {‖ {r}^{′} ‖}_{2}^{2} , \\ r ( k ) = {V}_{k} - {\hat{V}}_{k} ( θ ) , \\ {r}^{′} ( k ) = r ( k + 1 ) - r ( k ) , and \\ {θ}^{T} = ( {R}_{0}^{c h g} {R}_{1}^{c h g} {C}_{1}^{c h g} {A}_{D}^{c h g} {R}_{0}^{d i s} {R}_{1}^{d i s} {C}_{1}^{d i s} {A}_{D}^{d i s} {S}_{1} {S}_{2} ) ,\end{matrix}$$
where k is a vector index, θ is a parameter vector, r is a residual vector, and a is a weighting coefficient to control curvature of parameter fitting achieved by the optimization process.

19. The system of claim 15, wherein the processor-based device is further configured to:
derive at least one pulse component from one or more of: the voltage response, or the resultant battery characterization data; and
predict, using a battery state diagnostic machine learning model applied to the derived at least one pulse component, one or more of: a state of health (SoH) of the lithium-ion battery, or a state of charge (SoC) for the battery.

20. Non-transitory computer readable media comprising computer instructions executable on a processor-based device to:
cause measurement of voltage response data for a lithium-ion battery in response to a bipolar current pulse signal applied to the lithium-ion battery; and
determine using a bipolar pulse (BIP) model, based on the measured voltage response data, resultant battery characterization data representative of linear and nonlinear behavior of the lithium-ion battery.
